(19) United States
(12) Patent Application Publication
(10) Pub. No.: US 2017/0331040 A1
(43) Pub. Date: Nov. 16, 2017

(54) METHOD FOR MANUFACTURING HIGH-DENSITY ORGANIC MEMORY DEVICE

(71) Applicant: Seoul National University R&DB Foundation, Seoul (KR)

(72) Inventors: Takhee LEE, Seoul (KR); Younggul SONG, Seoul (KR); Jin-Kyun LEE, Incheon (KR)

(73) Assignee: Seoul National University R&DB Foundation, Seoul (KR)

(21) Appl. No.: 15/528,226

(22) PCT Filed: Apr. 29, 2015
(86) PCT No.: PCT/KR2015/004358

§ 371 Date: May 19, 2017

(30) Foreign Application Priority Data
Nov. 24, 2014 (KR) 10-2014-0164696

(51) Int. Cl. H01L 51/00; H01L 51/10; H01L 51/05

(52) U.S. Cl. CPC H01L 51/0018; H01L 51/0508; H01L 51/10

(57) ABSTRACT

A method for manufacturing an organic memory device is disclosed. According to one embodiment, the method comprises the steps of: forming a first electrode on a substrate; forming an organic active layer on the first electrode; and forming a second electrode on the organic active layer through an orthogonal photolithography technique using a fluorinated material.

### TECHNICAL FIELD

The present disclosure generally relates to a method for manufacturing an organic memory device. More particularly, the present disclosure relates to a method for manufacturing a high-density organic memory device by forming a second electrode on an organic active layer using a photolithography method to manufacture an organic memory device having a structure in which a first electrode, the organic active layer, and the second electrode are sequentially stacked on a substrate.

### BACKGROUND ART

Generally, an organic material has a variety of advantages, such as a very inexpensive cost, and the organic material may be applicable to a bendable flexible substrate, used in a large-area printing process, and the like so that research on an organic memory using the organic material is actively proceeding. Particularly, an organic material-based resistive memory, that is, an organic resistive memory, has a structure in which an organic active layer are disposed between intersecting electrodes. The organic active layer enters into a bistable resistance state, that is, a high resistance state or a low resistance state, according to a magnitude of a voltage applied through the upper and lower electrodes, and thus it is possible to distinguish between 0 and 1.

Specifically, when an electrode is formed on the organic active layer in a manufacturing process of an organic memory device, there is a limitation in that a typical photolithography process cannot be applied to the forming of the electrode on the organic active layer without modification. This causes a problem in that a memory device of a desired structure may be difficult to implement due to a possibility of a characteristic of the organic active layer being varied or a structure thereof being damaged since a typical solvent used in a photolithography process dissolves an organic material that configures the organic active layer as well as a typical photoresist material.

Accordingly, in a general organic memory manufacturing process, a thermal deposition process is mainly used when an electrode is formed on an organic active layer, as disclosed in, for example, Korean Patent Application Publication Nos. 10-2007-0112565 and 10-2007-0079432. The thermal deposition process is a process of heating and evaporating a source, which includes a metallic material for forming an electrode, to enable evaporated metallic particles to be deposited in a predetermined pattern on an organic targeted active layer. However, it is necessary to form a metal pattern having a linewidth that is less than or equal to about 10 micrometers (μm) using photolithography to manufacture a highly integrated device. Accordingly, there is a desperate need for high integration technology enabling a photolithography technique to be applied to an organic memory device.

### DISCLOSURE

### Technical Problem

The present disclosure aims to address the above described problem and to provide various additional advantages, and particularly, an objective of the present disclosure is to provide a method for manufacturing a high-density organic memory device which is capable of forming an electrode of a desired pattern on an organic active layer using a fluorinated material having orthogonality that prevents a material used in a photolithography process and the organic active layer of the organic memory device from dissolving an organic substance.

### Technical Solution

The above described objective is provided by a method for manufacturing a high-density organic memory device according to the present disclosure.

A method for manufacturing a high-density organic memory device, which is provided according to one aspect of the present disclosure, is a method for manufacturing an organic memory device and includes forming a first electrode on a substrate, forming an organic active layer on the first electrode, and forming a second electrode on the organic active layer through orthogonal photolithography in which a fluorinated substance is used.

The organic active layer includes an organic substance whose resistance is varied according to an applied voltage. Particularly, the organic substance may include an organic material selected from a group consisting of polyimide:phenyl-C61-butyric acid methyl ester (PI:PCBM), poly(3-hexylthiophene) (P3HT), poly[3-(6-methoxy-hexyl)thiophene, Cu-tetracyanoquinodimethane (TCNQ), PCBM:TTF:PS, WPF-oxy-F, and Alq3/Al/Alq3.

Specifically, the forming of the second electrode includes stacking a photoresist layer, which includes the fluorinated substance, on the organic active layer; exposing the photoresist layer through a mask pattern; developing the exposed photoresist layer using a developing solvent that includes the fluorinated substance; stacking a second electrode material on the developed photoresist layer; and performing a lift-off process on the developed photoresist layer using a lift-off solvent that includes a fluorinated substance.

Here, the photoresist layer is formed by applying a photoresist solution that includes resorcinarene, a photoacid generator, hydrofluoroether (HFE), and propylene glycol methyl ether acetate (PGMEA). The photoresist solution may be manufactured through a mixing process of dissolving 8 to 15 weight % of a resorcinarene powder and 0.4 to 0.8 weight % of the photoacid generator in 85 to 91.5 weight % of a mixed solution in which HFE and PGMEA are mixed at a weight ratio of 4:1, and a filtering process of filtering particles using a filter which passes a particle that is smaller than or equal to 0.20 micrometers (μm). The developing solvent may include HFE, and the lift off solvent may be a solvent in which 90 to 95 weight % of HFE and 5 to 10 weight % of ethanol are mixed.

Meanwhile, the first electrode and the second electrode may each be formed using a conductive material that is selected from a group consisting of gold, silver, platinum, copper, cobalt, nickel, tin, aluminum, indium tin oxide, and titanium, or a combination of two or more thereof.

Further, a high-density organic memory device according to another aspect of the present disclosure is provided to include a first electrode formed on a substrate; an organic active layer formed on the first electrode; and a second electrode formed on the organic active layer through orthogonal photolithography in which a fluorinated substance is used.

### Advantageous Effects

As is described above, in accordance with the present disclosure, a high-density organic memory device may be implemented by applying photolithography when an organic memory device is manufactured so that there is provided an advantage in that the organic memory device may be realistically applicable to a variety of industries.

### DESCRIPTION OF DRAWINGS

FIG. 1 is a cross-sectional view schematically illustrating a structure of an organic memory device which is manufactured by a method for manufacturing a high-density organic memory device according to one embodiment of the present disclosure.

FIG. 2 is a flowchart schematically illustrating a process of the method for manufacturing a high-density organic memory device according to one embodiment of the present disclosure.

FIG. 3 is a schematic diagram illustrating a process of forming a second electrode on an organic active layer using photolithography in the method for manufacturing a high-density organic memory device according to one embodiment of the present disclosure.

FIG. 4 is a diagram exemplifying a high-density organic memory device which is manufactured by the method for manufacturing a high-density organic memory device according to one embodiment of the present disclosure.

FIGS. 5 to 14 are various graphs illustrating characteristics of the high-density organic memory device exemplified in FIG. 4.

### MODES OF THE INVENTION

Hereinafter, various embodiments of the present disclosure will be described with reference to the accompanying drawings as examples.

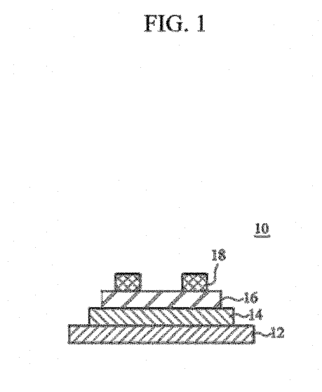

FIG. 1 is a cross-sectional view schematically illustrating a structure of an organic memory device which is manufactured by a method for manufacturing a high-density organic memory device according to one embodiment of the present disclosure.

Referring to FIG. 1, an organic memory device 10 which is provided according to one embodiment of the present disclosure has a structure in which a substrate 12, a first electrode 14, an organic active layer 16, and a second electrode 18 are sequentially stacked.

In the organic memory device 10 of the present disclosure, the substrate 12 may be made of silicon (Si) or silicon oxide (SiO₂) based material. A wafer and the like, which are generally used in a typical memory manufacturing field, may be used as the substrate 12 without modification.

The first electrode 14 may be formed using a metallic material that has conductivity. In the example shown in FIG. 1, the first electrode 14 is formed to have a pattern, such as lines which each have a constant width and are arranged in parallel with one another in a constant direction at regular intervals, and a lateral sectional view of one of the lines is shown in FIG. 1. A material of the first electrode 14 may be selected from a group consisting of gold, silver, platinum, copper, cobalt, nickel, tin, aluminum, indium tin oxide, and titanium, or a combination of two or more thereof.

The first electrode 14 is formed on a substrate based on an inorganic material such as silicon using typical general photolithography, but it is not limited thereto. For example, orthogonal photolithography, which will be described below, may also be used, and further one of other typical metallic material stacking techniques, which are already known in a semiconductor device manufacturing field, including deposition, sputtering, and the like may also be used in addition to the orthogonal photolithography.

The organic active layer 16 may be stacked by coating an organic substance on the first electrode 14. A method for stacking the organic substance may be performed by applying any one among various coating methods including spin coating, spray coating, dip coating, blade coating, roll coating, and the like. Also, the coating of the organic substance may be performed using other techniques which are well known in an organic memory device manufacturing field in addition to the above described coating methods.

The organic substance configuring the organic active layer 16 is an organic material whose resistance is varied according to an externally applied voltage, and is preferably a material having a strong mechanical property and a property of being heat stable. In embodiments, the organic substance may be selected from a group consisting of polyimide:6-phenyl-C61 butyric acid methyl ester (PI:PCBM), poly(3-hexylthiophene) (P3HT), poly[3-(6-methoxy-hexyl)thiophene, Cu-tetracyanoquinodimethane (TCNQ), PCBM:TTF:PS, WPF-oxy-F, and Alq3/Al/Alq3.

In one embodiment, PI:PCBM may be stacked as the organic active layer on the first electrode 14 through spin coating. PI:PCBM is a mixture in which PI and PCBM are dissolved in N-methyl-2-pyrrolidone (NMP). In one embodiment of the present disclosure, PI:PCBM is a precursor material, and, for example, PI:PCBM may be manufactured by mixing, at a predetermined ratio, a solution in which an amic acid (BPDA-PPD) solution is mixed with NMP at a constant ratio with a solution in which PCBM powder is dissolved in NMP at a different constant ratio.

When the PI:PCBM manufactured as described above is coated on the first electrode 14, it may be diluted by adding more NMP, which is a solvent component in order to adjust a thickness of the coated organic active layer. As an amount of NMP added is increased, it is expected that a thickness of the organic active layer 16 may be thinner. However, since the thickness of the organic active layer 16, which has an appropriate operation characteristic, is theoretically determined in advance, the amount of NMP added may be determined according to the thickness of the organic active layer 16. Each material for manufacturing PI:PCBM is commercially available from Aldrich, Sigma-Aldrich Company.

While PI:PCBM is described above as the organic substance, the organic substance is not limited thereto, and any one among various organic resistive materials including P3HT, poly3-(6-mthoxyhexyl)thipene, TCNQ, PCBM:TTF:PS, WPF-oxy-F, Alq3/Al/Alq3, and the like may also be used as the organic substance configuring the organic active layer 16.

The second electrode 18 is manufactured in the form of a plurality of parallel lines, which each have a linewidth and an interval similar to those of the first electrode 14, in a direction that is orthogonal to the first electrode 14. The second electrode 18 may be formed using a conductive material selected from a group consisting of gold, silver, platinum, copper, cobalt, nickel, tin, aluminum, indium tin oxide, and titanium, or a combination of two or more thereof.

Specifically, the second electrode 18 is formed on the organic active layer 16 through orthogonal photolithography in which a fluorinated substance is used. In particular, according to an embodiment, the orthogonal photolithography includes stacking a photoresist layer of the fluorinated substance on the organic active layer 16, exposing and transferring a pattern of the second electrode to the photoresist layer using ultraviolet light, developing and dissolving the exposed photoresist layer through a developing solvent based on the fluorinated substance, stacking a second electrode material such as, for example, gold, on the developed photoresist, and then forming the second electrode by melting the remaining photoresist layer using a lift-off solvent based on the fluorinated substance.

In the orthogonal photolithography, one important factor is that all of the photoresist and the developing and lift-off solvents are based on the fluorinated substance so as not to react with the organic active layer 16. The fluorinated substance is well known as a substance which does not react with an organic substance, and a solvent, such as hydrofluoroether (HFE) and the like, is known.

According to one embodiment, the photoresist of the fluorinated substance is manufactured by dissolving a resorcinarene powder and a photoacid generator in a mixed solution, which serves as a solvent, of HFE and propylene glycol methyl ether acetate (PGMEA). Both such developing and lift-off solvents which dissolve a resist substance may employ an HFE-based solvent.

According to a more specific embodiment, the photoresist layer is formed by applying a photoresist solution which includes resorcinarene, a photoacid generator, HFE, and PGMEA. The photoresist solution may be manufactured by dissolving and mixing 8 to 15 weight % of a resorcinarene powder and 0.4 to 0.8 weight % of the photoacid generator with 85 to 91.5 weight % of a mixed solution in which HFE and PGMEA are mixed at a weight ratio of 4:1, and filtering particles using a filter which passes only a particle that is smaller than or equal to 0.20 micrometers (μm). The developing solvent may include HFE, and the lift-off solvent may be a solution in which 90 to 95 weight % of HFE and 5 to 10 weight % of ethanol are mixed.

Also, in the orthogonal photolithography, another important factor is an environmental variable. A reason for that is because the fluorinated substance used in the orthogonal photolithography is affected according to environmental variables including a temperature, humidity, an amount of light in an exposing process, and the like. However, a typical photolithography process is performed in a clean room environment in which a temperature and humidity are uniformly controllable, and thus an environmental variable that may realistically be sensitively controlled is the amount of light in the exposing process. Ultraviolet light used in the exposing process is irradiated with a constant intensity using a laser having a predetermined wavelength (for example, 416 nanometers (nm)) which is set according to exposure equipment. Therefore, in such an environment, the amount of light being irradiated may be controlled by controlling an irradiation time of the ultraviolet light. In the case in which the amount of light being irradiated is insufficient, that is, an exposure time is insufficient, a boundary of a pattern is not clearly developed when an exposed pattern is developed. On the other hand, in the case in which the amount of light being irradiated is excessive, that is, the exposure time is excessively long, there is a problem in that a formation of a precise pattern is difficult due to excessive melting around the boundary when the exposed pattern is developed. An appropriate range of the exposure time may be varied according to the kind of fluorinated substance configuring the photoresist, the kind of fluorinated substance which is used as a solvent, a wavelength or intensity of light which is used, a temperature, and humidity. Therefore, an appropriate exposure time may be empirically determined through experiments according to combinations of various variables.

The organic memory device 10 according to the present disclosure having the above described structure has a characteristic of a high-density integrated memory device since the second electrode 18, which is formed on the organic active layer 16, is formed using the orthogonal photolithography. For example, it is known that a typical memory device in which a second electrode is formed through a thermal deposition method has a linewidth of a pattern in the range of 50 to 100 μm, and a unit cell of about 100×100 μm² provides 8×8 bits of integration in a 1.9×1.9 mm² region. Comparing the organic memory device 10 of the present disclosure with the typical memory device, for example, when lines of the first electrode 14 which each have a thickness of about 25 nm, a linewidth of about 10 μm, and an interval of about 30 μm, the organic active layer 16 having a thickness of about 15 μm, and lines of the second electrode 18 which each have a thickness of about 30 nm, a linewidth of about 10 μm, and an interval of about 30 μm are formed on the substrate 12 having a thickness of 270 nm through micro photolithography using ultraviolet light, a size of a cell may be decreased by about 10×10 μm² and thus a high integration of 4-K bits (that is, 64×64=4092 bits) may be provided in a 1.9×1.9 mm² region.

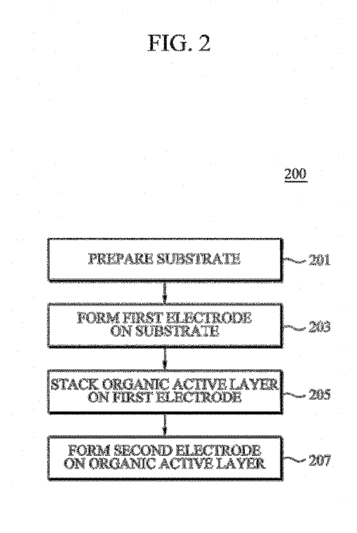

FIG. 2 is a flowchart schematically illustrating a process of a method 200 for manufacturing a high-density organic memory device according to one embodiment of the present disclosure.

The method 200 for manufacturing a high-density organic memory device, which is provided according to one aspect of the present disclosure, is a method for manufacturing the organic memory device 10 (See, FIG. 1) and includes, first, preparing the substrate 12 in Operation 201, forming the first electrode 14 on the substrate in Operation 203, forming the organic active layer 16 on the first electrode in Operation 205, and forming the second electrode 18 on the organic active layer through orthogonal photolithography in which a fluorinated substance is used in Operation 207.

Operation 201 of preparing the substrate is an operation of preparing a silicon (Si) or silicon oxide (SiO₂) based wafer or substrate.

In Operation 203 of forming the first electrode on the substrate, a metallic material, for example, such as aluminum (Al), is manufactured in the form of parallel lines, which each have a thickness of about 20 to 25 μm, a linewidth of about 10 μm, and an interval of about 30 μm, on the substrate 12 using one among various known techniques including an electron-beam evaporation method, sputtering, photolithography, and the like.

Thereafter, in Operation 205 of forming the organic active layer 16, the organic active layer 16 is stacked with a thickness of, for example, about 15 nm, by spin coating, for example, PI:PCBM thereon.

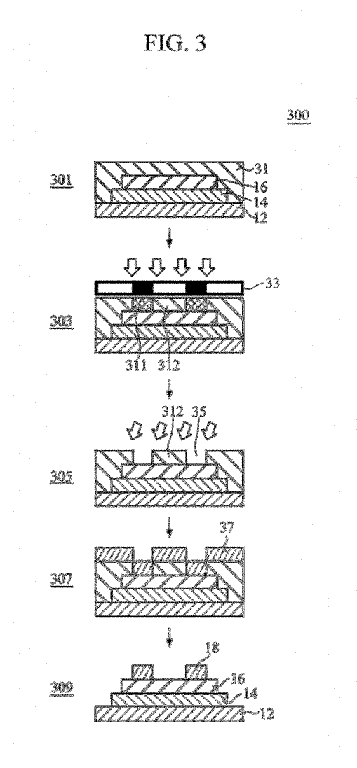

Afterward, in Operation 207 of forming the second electrode on the organic active layer, a second electrode made of gold (Au) may be formed through an orthogonal photolithography method, that is, a photolithography method using a resist and a solvent which are based on a fluorinated substance. Operation 207 of forming the second electrode will be described in more detail below with reference to FIG. 3.

FIG. 3 is a schematic diagram illustrating the process of forming the second electrode on the organic active layer using photolithography in the method for manufacturing a high-density organic memory device according to one embodiment of the present disclosure.

Referring to FIG. 3, in the process of manufacturing the organic memory device 10 (See, FIG. 1), Operation 207 of forming the second electrode on the organic active layer (See, FIG. 2), that is, an orthogonal photolithography process 300, is specifically shown in detail. As shown in the drawing, the process 300 of forming the second electrode includes a process 301 of stacking a photoresist layer on the organic active layer, an exposing process 303, a developing process 305, a process 307 of stacking a second electrode substance on the photoresist layer, and a lift-off process 309.

The process 301 of stacking the photoresist layer on the organic active layer is a process of forming a photoresist layer 31 on the organic active layer 16 in a state in which the first electrode 14 and the organic active layer 16 are sequentially stacked on the substrate 12.

The exposing process 303 disposes a mask 33, which has a pattern (for example, lines arranged in parallel at regular intervals) of the second electrode that is to be formed, immediately over the photoresist layer 31, and then irradiates the mask 33 with ultraviolet light at a right angle. Thus, the photoresist layer 31 is divided into an exposed portion 311 that is exposed to the ultraviolet light and a non-exposed portion 312 according to the pattern on the mask.

Thereafter, in the developing process 305, the exposed portion 311 that is exposed to the ultraviolet light is melted and removed using a solvent of a fluorinated substance, and only the non-exposed portion 312 remains, thereby developing a second electrode pattern 35.

Next, in the process 307 of stacking the second electrode substance on the photoresist layer, a second electrode layer 37 having a predetermined thickness is deposited on the photoresist layer, in which only the non-exposed portion 312 remains, as, for example, gold (Au) using an electron-beam evaporator. The second electrode layer 37 comes into contact with the organic active layer 16 at a portion corresponding to the second electrode pattern 35, and is stacked on the non-exposed portion 312 of the photoresist layer at the remaining portion of the second electrode layer 37.

Lastly, in the lift-off process 309, when the non-exposed portion 312 of the photoresist layer is melted and removed using a lift-off solvent of a fluorinated substance, the remaining portion of the second electrode layer 37 except for the portion corresponding to the second electrode pattern 35 is removed together with the non-exposed portion 312 of the photoresist layer, and thus only the second electrode 18 remains.

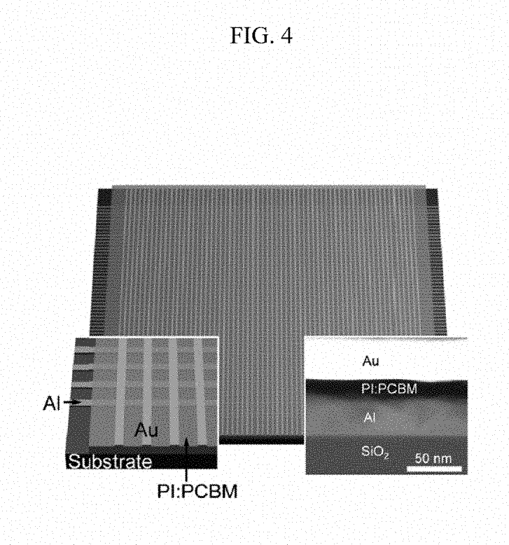

FIG. 4 is a diagram exemplifying a high-density organic memory device which is manufactured by a method for manufacturing a high-density organic memory device according to one concrete embodiment of the present disclosure.

Referring to FIG. 4, the organic memory device manufactured according to one concrete embodiment of the present disclosure is exemplified.

In this embodiment, the substrate 12 is prepared with about 270 nm of a silicon oxide substrate, and is cleaned using acetone, isopropanol, and deionized water. The first electrode 14 is formed with lines, which each have a thickness of about 20 nm, an interval of about 30 μm, and a linewidth of about 10 μm, using typical photolithography. To improve uniformity of the first electrode 14 which has been formed, the first electrode 14 is exposed to ultraviolet-ozone (UV-ozone) for about 10 minutes.

Thereafter, the organic active layer 16 is stacked by spin coating PI:PCBM on the first electrode 14. In this case, PI:PCBM is a precursor material, and, for example, a PI:PCBM solution is manufactured by mixing about 3 parts of a solution in which about 0.5 weight % of a PCBM powder is dissolved in NMP with respect to about 20 parts of a solution in which a BPDA-PPD solution is mixed with about 10 weight % of NMP, that is, at a ratio of 3:20. In the present example, a thickness of the coated organic active layer 16 is about 15 nm, and thus NMP is added at a ratio of about 113 parts with respect to about 23 parts of the mixed PI:PCBM solution. Afterward, soft baking is performed at a temperature of 120° C. for about 5 minutes in a glove box in which nitrogen is filled. To remove foreign materials after the soft baking, a cotton swab with methanol is used to wipe the foreign materials, and then hard baking is performed at a temperature of 300° C. for 30 minutes.

Next, a fluorinated photoresist solution is spin coated on the organic active layer 16, and baking is performed at a temperature of 75° C. for 3 minutes under yellow light. At this point, the fluorinated photoresist solution is a solution including resorcinarene, a photoacid generator, HFE, and PGMEA. Particularly, the fluorinated photoresist solution that is used is manufactured by dissolving about 10 weight % of a semi-perfluoroalkyl resorcinarene powder and about 0.5 weight % of a N-nonafluorobutanesulfonyloxy-1,8-naphthalimide photoacid generator in 89.5 weight % of a mixed solution in which HFE-7500 (3-ethoxy-1,1,1,2,3,4,4,5,5,6,6,6-dodecafluoro-2trifluoromethylhexane) and PGMEA are mixed at a weight ratio of 4:1, and then filtering particles using a filter which passes only a particle that is smaller than or equal to 0.20 μm.

Thereafter, the coated photoresist layer is exposed to ultraviolet light (having a wavelength of 416 nm and an intensity of about 8 mW/cm²) for 4 seconds through a photomask having lines, each of which has a linewidth of 10 μm, in an orthogonal direction with respect to the first electrode. Next, baking is performed at a temperature of 75° C. for about 3 minutes, and then the exposed photoresist layer is developed using HFE-7200 as a solvent. Further, a gold (Au) layer having a thickness of about 30 nm is stacked on the developed photoresist layer, and a lift-off process is performed using a lift-off solvent in which ethanol and HFE-7200 are mixed at a volume ratio of 5:95. Consequently, the second electrode is formed on the organic active layer of PI:PCBM.

Through such processes, as shown in FIG. 4, an organic memory device having a size of 1.9×1.9 mm² is manufactured, wherein 64 lines of a lower electrode (that is, the first electrode), each of which is formed with aluminum (Al) on a silicon oxide substrate and has a linewidth of 10 μm, the organic active layer made of PI:PCBM, and 64 lines of an upper electrode (that is, the second electrode), each of which is formed with gold (Au) on PI:PCBM through the photolithography and has a linewidth of 10 μm, intersect in the organic memory device. In this organic memory device, a size of each cell at each of which the lower electrode line and the upper electrode line intersect is about 10×10 μm² and is very small, and high integration of 4-K bits (that is, 64×64=4092 bits) is provided in a 1.9×1.9 mm² region.

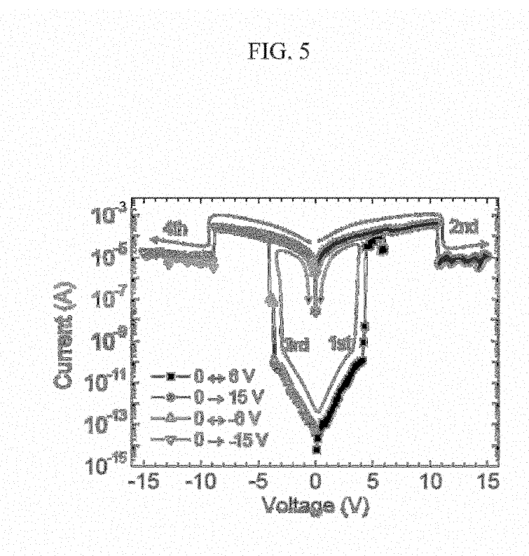

A 4-K class high-density organic memory device manufactured as described above represents a satisfied stable electrical characteristic and further provides a high yield compared to a low-density organic memory device, and these will be described below with reference to FIGS. 5 to 14.

FIGS. 5 to 14 show a plurality of graphs illustrating various characteristics which are observed from the high-density organic memory device exemplified in FIG. 4.

FIG. 5 is a graph illustrating a current-voltage (I-V) characteristic with respect to a single cell of the high-density organic memory device exemplified in FIG. 4. Here, an external voltage is applied to the Au electrode in a state in which the Al lower electrode is grounded. This memory cell is turned on at 4.1 volts (V) (or, −3.7 V) and is turned off at 10.6 V (or, −8.8 V) according to a positive (or, negative) voltage sweep, and thus the memory cell shows a typical nonvolatile unipolar switching behavior. This may be described as a PCBM molecule, which is embedded in a PI matrix of the PI:PCBM that is used as the organic active layer, serving to hold or release a charge carrier, and thereby realizing a bistable switching behavior.

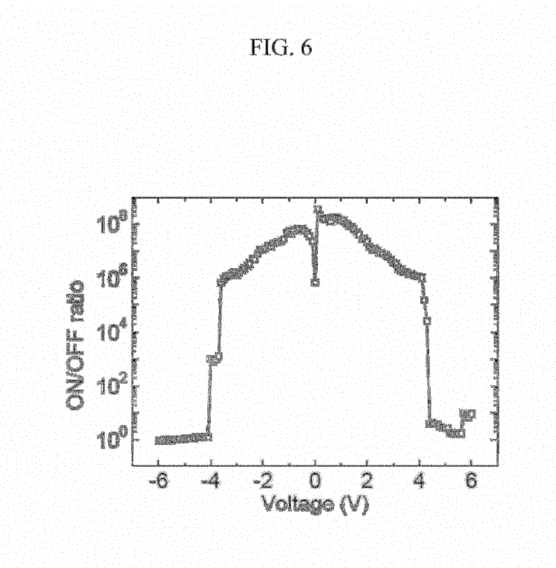

FIG. 6 is a graph illustrating a current ON/OFF ratio as a function of an applied voltage in a memory cell of the organic memory device of FIG. 4. As shown in the drawing, the memory cell shows a high speed ON/OFF ratio over 106 in the range of ±4 V.

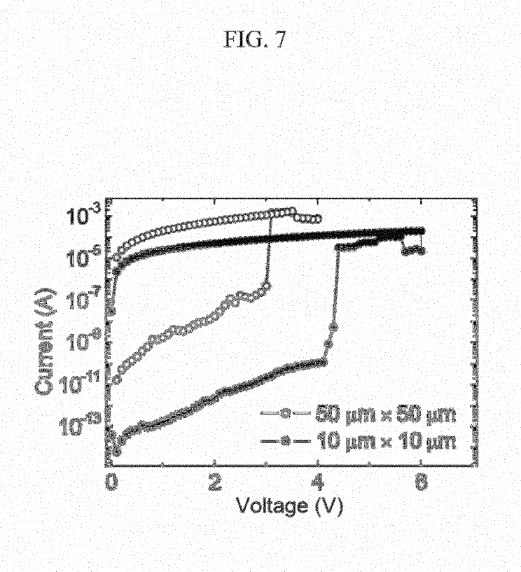

FIG. 7 shows a graph comparing I-V characteristics between the organic memory device (having a cell size of 10×10 μm²) and an organic memory device (having a cell size of 50−50 μm²) using a typical shadow masking method. These two devices show a similar switching behavior in which a current is abruptly increased at a threshold voltage Vth at which a memory cell is turned on, but there is a difference in current level between the two devices. Such a difference in current level may be described as being due to a difference in cell size.

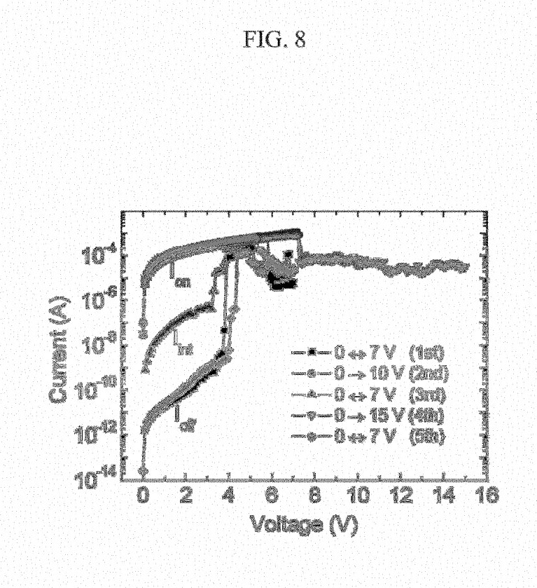

FIG. 8 shows that two or more resistance change states may exist in a memory cell of the organic memory device of FIG. 4. The memory cell is switched from an OFF state to an ON state by a first voltage sweep (that is, a double sweep between 0V and 7V). Thereafter, the memory cell is switched to an intermediate stage INT by a second voltage sweep (that is, a double sweep between 0V and 10V) and a third voltage sweep (that is, a double sweep between 0V and 7V). Afterward, the memory cell returns to the OFF state by a fourth voltage sweep (that is, a double sweep between 0V and 15V).

As is described above, the results shown in FIGS. 5 to 8 show that the organic memory device manufactured according to the present disclosure is not adversely affected by a fluorinated component, and thus operates normally.

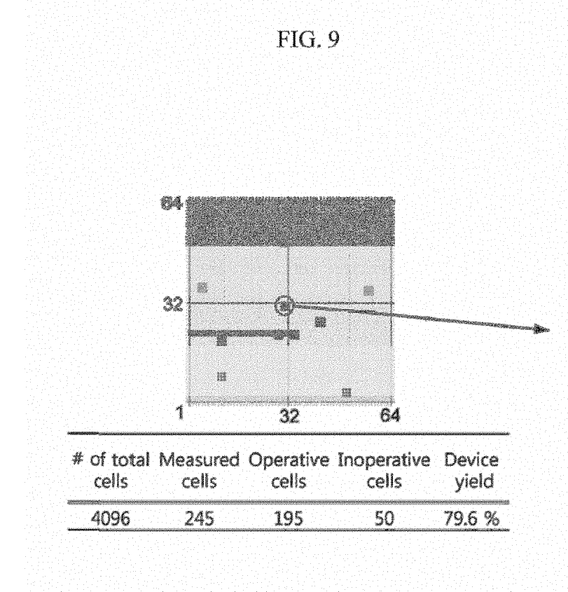

FIG. 9 is a schematic diagram illustrating regions which are selected for measurement from the 4-K bit-organic memory device of FIG. 4 and a table illustrating information of the organic memory device. In the schematic diagram, the selected regions are arbitrarily selected for measuring uniformity of memory cells which are arranged at the organic memory device. As shown in the table, a result of the measurement is that the total number of memory cells is 4096, the number of measured memory cells among the total memory cells is 245, the number of memory cells which operate normally among the measured memory cells is 195, and the number of memory cells which operate abnormally among the measured memory cells is 50, so that a yield is 79.6%. Such a yield is a very high yield compared to a 60 to 70% yield of a typical organic memory device. Such a high yield may be understood as showing that the uniformity of the memory cells may be more easily secured with a high density as electrodes are integrated on the organic active layer which is spin coated.

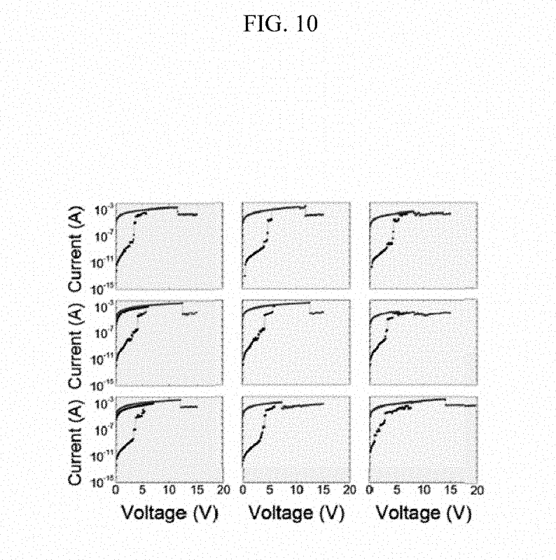

FIG. 10 is graphs which illustrate an I-V characteristic of each of 9 memory cells that is measured at a single region including the 9 memory cells among the regions shown in the schematic diagram of FIG. 9. As shown in the drawing, it can be seen that a current level, the threshold voltage Vth, and an ON/OFF behavior are similar in the 9 memory cells from each other.

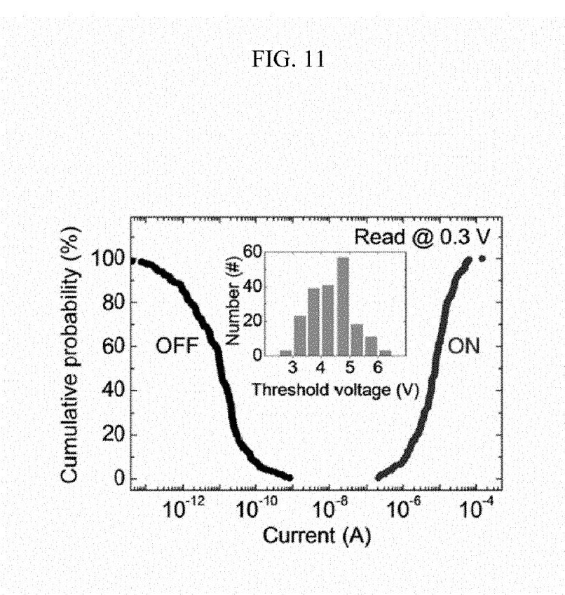

FIG. 11 illustrates a distribution of ON/OFF currents and a threshold voltage of 195 memory cells which operate normally that are shown in FIG. 9, and a good operating characteristic thereof.

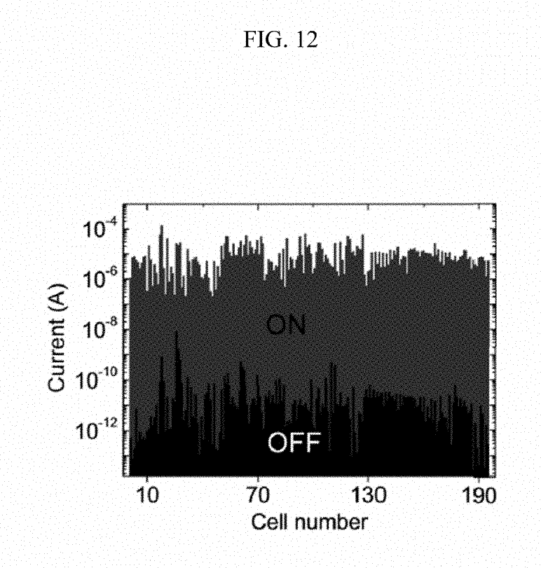

FIG. 12 illustrates a logarithmic scale with respect to a statistical distribution of the ON/OFF current of each of the 195 memory cells which operate normally that are shown in FIG. 9. It can be seen that a difference between the ON current and the OFF current in most of the 195 memory cells is significantly large.

FIG. 12 illustrates the statistical distribution of the ON/OFF current of each of the 195 memory cells which operate normally that are shown in FIG. 9. The statistical distribution in FIG. 12 is represented with the logarithmic scale. It can be seen that the difference between the ON current and the OFF current in most of the 195 memory cells is significantly large.

As is described above, the results shown in FIGS. 9 to 12 show that the uniformity of the memory cells which are arranged at the organic memory device manufactured according to the present disclosure is good.

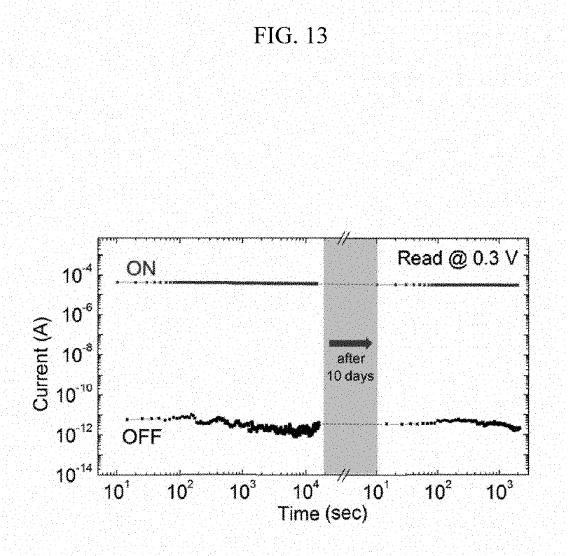

FIG. 13 illustrates a result of a retention test which is performed with respect to the organic memory device of FIG. 4, and this result is used for the purpose of understanding persistence of a memory storage. First, a second test is performed ten days after a first test, and as a result thereof, it can be seen that there is no significant variance in switching performance of the organic memory device even after ten days have passed.

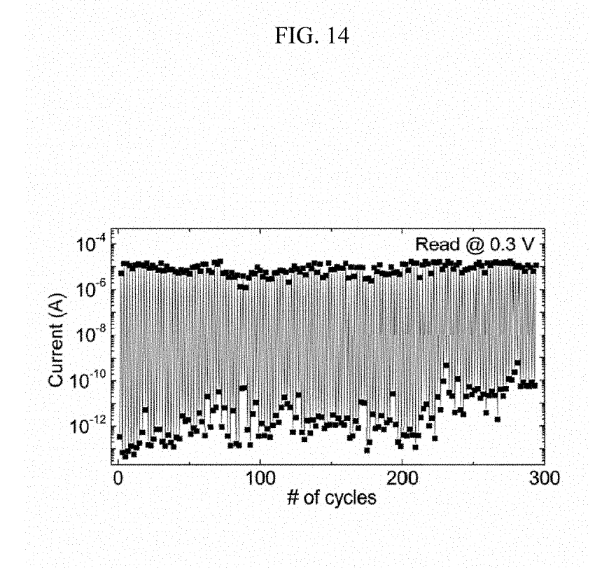

FIG. 14 is a graph illustrating a result of a direct current (DC) sweep endurance test which is performed with respect to the organic memory device of FIG. 4. DC voltage sweeps are applied to the organic memory device to repeatedly turn the organic memory device on and off. Although variance occurs such that a current level is somewhat increased at the OFF current, it can be seen that the organic memory device maintains a high speed ON/OFF ratio of over 104 while being repeatedly switched about 300 times. The increase of the OFF current may be understood as being due to an accumulation of charges during continuous ON/OFF operations, and such a problem may be addressed by adjusting a ratio between ON/OFF voltages.

While the present disclosure has been described above with reference to concrete embodiments, various alternations, modifications, and equivalent substitutions can be derived by those skilled in the art without departing from the scope and spirit of the appended claims. Therefore, the detailed description should be construed as illustrative only and not as limiting the present disclosure.

1. A method for manufacturing a high-density organic memory device, comprising:
forming a first electrode on a substrate;
forming an organic active layer on the first electrode; and
forming a second electrode on the organic active layer through orthogonal photolithography in which a fluorinated substance is used.

2. The method of claim 1, wherein the organic active layer includes an organic substance whose resistance is varied according to an applied voltage.

3. The method of claim 2, wherein the organic substance includes an organic material selected from a group consisting of polyimide:phenyl-C61-butyric acid methyl ester (PI:PCBM), poly(3-hexylthiophene) (P3HT), poly[3-(6-methoxy-hexyl)thiophene, Cu-tetracyanoquinodimethane (TCNQ), PCBM:TTF:PS, WPF-oxy-F, and Alq3/Al/Alq3.

4. The method of claim 1, wherein the forming of the second electrode includes:
stacking a photoresist layer, which includes the fluorinated substance, on the organic active layer;
exposing the photoresist layer through a mask pattern;
developing the exposed photoresist layer using a developing solvent that includes the fluorinated substance;
stacking a second electrode material on the developed photoresist layer; and
performing a lift-off process on the developed photoresist layer using a lift-off solvent that includes the fluorinated substance.

5. The method of claim 4, wherein the photoresist layer is formed by applying a photoresist solution that includes resorcinarene, a photoacid generator, hydrofluoroether (HFE), and propylene glycol methyl ether acetate (PGMEA).

6. The method of claim 5, wherein the photoresist solution is manufactured through a mixing process of dissolving 8 to 15 weight % of a resorcinarene powder and 0.4 to 0.8 weight % of the photoacid generator in 85 to 91.5 weight % of a mixed solution in which HFE and PGMEA are mixed at a weight ratio of 4:1, and a filtering process of filtering particles using a filter which passes a particle that is smaller than or equal to 0.20 micrometers (μm).

7. The method of claim 5, wherein the developing solvent includes HFE.

8. The method of claim 5, wherein the lift-off solvent is a solvent in which 90 to 95 weight % of HFE and 5 to 10 weight % of ethanol are mixed.

9. The method of claim 1, wherein the first electrode and the second electrode are each formed using a conductive material selected from a group consisting of gold, silver, platinum, copper, cobalt, nickel, tin, aluminum, indium tin oxide, and titanium, or a combination of two or more thereof.

10. A high-density organic memory device comprising:
a first electrode formed on a substrate;
an organic active layer formed on the first electrode; and
a second electrode formed on the organic active layer through orthogonal photolithography in which a fluorinated substance is used.
